(19) United States
(12) Patent Application Publication
(10) Pub. No.: US 2013/0298958 A1
(43) Pub. Date: Nov. 14, 2013

(54) Portable rigid solar photovoltaic module and applications

(71) Applicant: Eduard Kopylov, Aurora, CO (US)

(72) Inventor: Eduard Kopylov, Aurora, CO (US)

(21) Appl. No.: 13/506,735

(22) Filed: May 14, 2012

(51) Int. Cl. H01L 31/05

(52) U.S. Cl. 136/244

(57) ABSTRACT

A frameless photovoltaic module constructed as a laminated sandwich comprising an optically transparent plastic film glazing layer, an optically transparent upper adhesive layer, a matrix of PV cells, a middle layer adhering said PV cells to a PV cells back lining layer consisting of a matrix of an individual plastic film tiles having the same quantity, footprints and arrangement as the PV cells and another sides of said plastic film tiles are adhered to a PV module rigid base sheet, said plastic film glazing layer, being adhered to said PV cells and to said rigid base sheet, in spaces between said PV cells and the rigid base sheet peripheral areas, forms in-folds in the grooved spaces between said PV cells, where said in-folds allow compensation for thermal expansion and contraction of said plastic film glazing. Interspaces between adjacent PV cells chamfered corners are arranged with mounting holes reinforced by eyelets.

### CROSS-REFERENCE TO RELATED APPLICATIONS

Not Applicable

### FEDERALLY SPONSORED RESEARCH

Not Applicable

### SEQUENCE LISTING OF PROGRAM

Not Applicable

### FIELD OF THE INVENTION

The present invention relates to solar photovoltaic modules for converting light into electrical energy and more particularly relates to portable rigid photovoltaic modules with plastic film glazing, their design and applications.

### BACKGROUND OF THE INVENTION

### Prior Art

The are two kinds of conventional photovoltaic modules for converting sun light into electrical energy. One kind is designed for long term applications, normally to be installed on roofs or canopies. Majority of them are rigid construction with front glass cover protecting photovoltaic cells. Some of the modules are flexible and, generally, have less efficient solar PV cells. Glass covered PV modules are heavy and fragile, require extra care in handling and storage.

Another kind of conventional photovoltaic modules is designed for portable applications and they are, generally, flexible or foldable with fabric or plastic substrates. Majority of portable PV modules have low efficiency photocells.

Some solar power generating systems application require PV modules to be high efficiency, light weight, rigid, free of fragile material ((glass) and easily adaptable for multiple portable applications. One of such applications is solar-electric propulsion power for boats, where such PV modules can be used as photovoltaic canopies. Such modules can be easily installed using simple mounting means and can be easily removed for other applications related to solar-electric power generating or transportation and storage.

Another application for portable rigid PV modules can be as a car battery charging dash-board shade panel installed below a car windshield.

Also, such modules can be used in portable temporary plug-in connected solar-electric power generating systems.

It is need for such PV module which simple in design and inexpensive for production. Such modules can be designed for short term (portable application only) using less expensive materials, however, life cycle of a such product could be long due to short exposure of such PV modules to the element, comparing with more expensive modules designed for long term installation on a roof (about 20 years).

Some prior art PV modules ideas offer an arrangement which can be related to the field of the invention, for example, a solar cell module presented by Gay in U.S. Pat. No. 4,461,922. This module comprises a transparent substrate (suggested to be glass or plastic), a thin film of silicon/hydrogen solar cells deposed on said transparent substrate and passing through light to secondary solar cells mounted on a second substrate with top layer of isolating material. It looks that like, Gay proposal to use glass or plastic material for the transparent substrate and metal, plastic (or the like) for the second substrate was taken lightly because these materials have significantly different thermal expansion properties to be considered in the PV module design. This patent does not teach how to deal with that.

Junction boxes attachéd to the transparent substrate of the module make stacking such modules impractical.

The photovoltaic panel of Flaherty, U.S. Pat. No. 7,531,740 and U.S. Pat. No. 7,557,291 presented as laminated sandwich of a protective upper layer, adhesive, middle layer of PV cells, adhesive, rigid lower layer, adhesive tape layer. All this adhered layers of the laminated sandwich are framed by perimeter frame.

The Flaherty design of a PV module has several disadvantages:
a. The upper protective layer of the module is one solid sheet of fluorinated ethylene propylene (FEP) film with linear thermal coefficient of expansion is about 75×10⁻⁶ in/in ° F., the rigid lower layer material used in the Flaherty PV module is a fiber reinforced plastic (FRP) has linear thermal coefficient of expansion is about 15×10⁻⁶ in/in ° F. Such significant difference in the thermal properties creates physical stresses resulting in bulging and pill off of the layers or/and bending module.
b. The module frame adds extra material and labor cost.
c. The module termination is arranged by two output conductors extending from the module middle layer into j-box attached to the upper layer of said module. Presence of the outside j-box creates problems for the modules stacking during transportation and storage.
d. Proposed thickness of the lower “rigid” layer of the module is 0.103 inch does not provide necessary structural rigidity for portable applications using frameless design of a PV module.

The solar cell module proposed by Kataoka, U.S. Pat. No. 5,582,653, comprises a transparent film layer, a transparent resin filler layer, photovoltaic elements, a rear side filler, back face protective film, a back face reinforcing member. The patent deals extensively with a problem of UV spectrum absorption. This patent does not address problem of differences of linear thermal expansion coefficients between the transparent film layer and the back face reinforcing member. Also, it does not offer any detailed arrangement of the module output outside termination.

Concerning PV module applications ideas in the prior art, it would be relevant to present Pizzuto U.S. Pat. No. 8,002,349 disclosing “Chair provision with an apparatus for converting solar energy to power electric devices”. This patent deals with a folding chair equipped by a small solar panel attached to the chair by a telescopic goose neck supporting element. The solar panel in this invention is small, does not serve well as a sun rays shielding canopy, designed to be held by the telescopic goose neck having very limited weight loading capacity, plus, the solar panel size is limited by intension to hide it into a back rest of the chair. This panel is designed to power very small load and is not suitable for such applications like a boat propulsion system or other similar load capacity applications.

### OBJECTS OF THE INVENTION

The are following objects of the present invention:
a. Provide a rigid, light weight PV module suitable for portable applications.
b. PV module shall not contain fragile material (glass), it shall have dimensions to be easily handled by a one person.
c. The PV module shall have high efficiency.
d. The PV module shall have low, flat profile for compact stacking for transportation and storage.
e. The PV module shall withstand thermal radiation of sun without visible distortion of shape or violation of physical integrity.
f. The PV module shall have plurality of mounting holes reinforced by eyelets for attachment to mounting elements in different applications.
g. The PV modules shall be able to be connected into a portable solar power generating system using power cords and dedicated quick connecting plugs.
h. To provide additional design style of the portable PV module for automotive application.
i. The PV module of simple design, low cost, easy to manufacture.
j. The PV module to be equipped with a foldable mounting structure for use with a foldable armchair for convenience of use, transportation and storage.

### SUMMARY OF THE INVENTION

All pointed out deficiencies of the Prior Art can be solved by a proposed new concept of a portable rigid PV module meeting objective of the invention objectives stated above.

The inventive module is frameless laminated sandwich comprising an optically transparent front plastic film glazing layer, an optically transparent upper adhesive layer, a PV cells layer which is a matrix of electrically connected PV cells, adhered by a middle adhesive layer to a PV cells back lining layer comprising a plurality of individual plastic film tiles, where one side of the each said plastic film tile is adhered to the back of respective PV cell and another side of said plastic film tiles is adhered to a PV module rigid base sheet with bus conductors strips and output cord connection chamber.

Interspaces between adjacent PV cells chamfered corners are arranged with mounting holes drilled through the front plastic film glazing layer and the PV module rigid base sheet and each said mounting hole is reinforced by an eyelet enhancing attachment of the module laminated sandwich system to the PV module base sheet. The PV cells back lining plastic film tiles, having the same footprint as the PV cells and being spaced the same way as the PV cells, form grooves in the spaces between them PV cells allowing said front plastic film glazing layer to be adhered to the PV module rigid base sheet and to form in-folds which allow a compensation for expansion and contraction of said front plastic film glazing layer due to the difference of thermal linear expansion coefficients between the plastic film glazing and the PV module rigid base sheet.

This kind of PV module is very suitable for portable PV canopy applications including portable solar/electric propulsion systems for boats and other applications requiring, rigid, light weight, non-fragile, thin profile PV module with plurality of reinforced mounting holes.

Proposed PV module can be easily used with an arm chair as a solar/electric power canopy using simple removable structure presented in the invention.

### DRAWINGS-FIGURES

In the drawings, closely related figures have the same number but different alphabetic suffixes.

FIG. 1 Shows isometric view of the layers comprising the inventive PV module.

FIG. 2 Shows isometric view of the assembled inventive PV module with output cord connection chamber cover being removed.

FIG. 2A Shows enlarged detail ‘A’ of the output cord connection chamber.

FIG. 3 Shows isometric view of the assembled inventive PV module with location of section B-B.

FIG. 3A Shows the section A-A view detail.

FIG. 4 Shows isometric view of the assembled inventive PV module with location of section C-C.

FIG. 4A Shows the section C-C view detail.

FIG. 5 Shows the inventive PV module arranged for automotive applications.

FIG. 5A Shows installation detail of the inventive PV module in an automobile.

FIG. 5B Shows side view of the PV module inside an automobile.

FIG. 6 Shows the inventive PV modules connected in a portable system application.

FIG. 7 Shows the inventive PV module with a detachable and foldable structure for mounting on a foldable armchair.

FIG. 7A Shows a detachable and foldable mounting structure for the inventive PV module to be mounted on an armchair.

FIG. 7B Shows detail of attachment of one a rear frame member to an armchair back support.

FIG. 7C Shows detail of attachment of the inventive PV module to the detachable and foldable structure.

FIG. 8 Shows detail of the removable and foldable structure supporting two inventive PV modules.

FIG. 8A Shows two inventive PV modules with the removable and foldable structure for being mounted on a foldable armchair.

FIG. 9 Shows isometric view of the inventive PV modules being mounted on the supporting structures attached to foldable arm chairs and used in a boat as solar/electric power canopies.

FIG. 10 Shows isometric view of the inventive PV modules being mounted on the supporting structures attached to foldable arm chairs and used in a pontoon boat as solar/electric power canopies.

### DETAILED DISCLOSURE OF PREFERRED EMBODIMENTS

Although specific features of the invention are shown in some drawings and are not others, this for convenience only as feature may be combined with any or all of other features in accordance with the invention.

While preferred illustrative embodiments of the invention are described below, it will be apparent to those skilled in the art that various changes and modifications may be made without departing from the invention. The appended claims are intended to cover all changes within spirit of the invention.

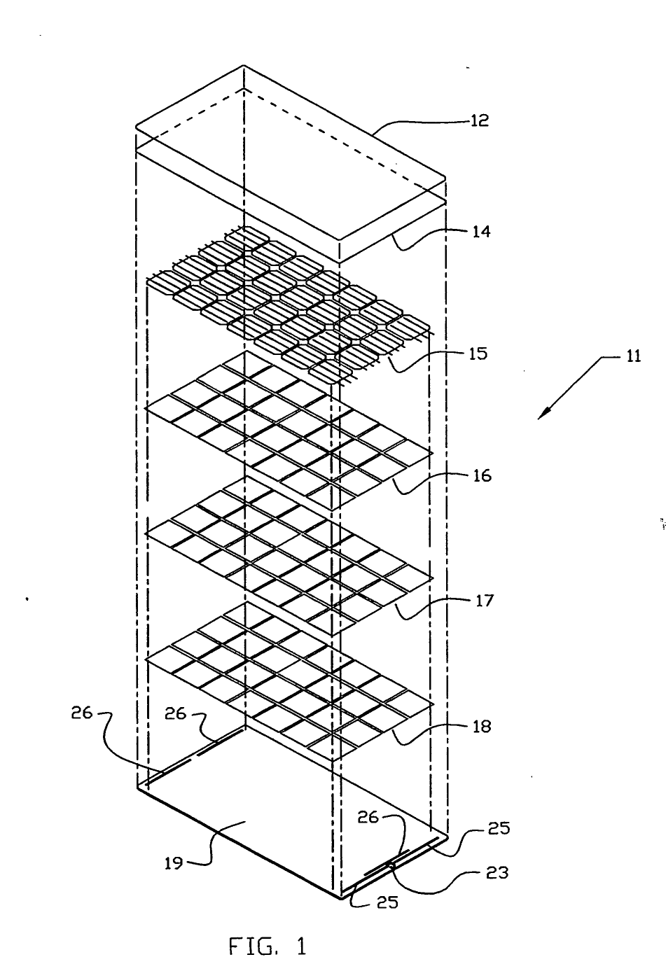

Preferred embodiments of the inventive PV module, mounting accessories and applications are illustrated in FIG. 1-FIG. 10.

Referring now to FIG. 1, which is an exploded isometric view of the inventive PV module 11 being presented as a frameless laminated sandwich comprising an optically transparent front plastic film glazing layer 12, an optically transparent upper adhesive layer 14, a PV cells layer 15 as a matrix of electrically connected PV cells, a middle adhesive layer 16 can be provided with PV cells back lining layer 17 consisting of a plurality of plastic film tiles matching quantity, footprint and arrangement of the PV cells. Another side of said plastic film tiles is adhered to a PV module rigid base sheet 19 by a lower adhesive layer 18. Said rigid base sheet 19 is equipped with bus conductor strips 25, 26 and an output cord connection chamber 23.

The front plastic film glazing layer 12 can be any suitable optically transparent material manufactured for PV module applications, of suitable thickness to withstand abuses of portable application, for example, FEP, FTFE. Also, lower cost UV stabilized acrylic or PET plastic films can be used for a short term portable PV module applications. The front plastic film glazing layer material can be provided with the optically transparent heat activated layer 14.

The plastic tiles 17 can be made from PET plastic provided with heat activated layer 16, adhesive 18 can be applied separately, additionally, plastic tiles 17 can be made of EVA plastic film combining 16, 17 and 18 layers in one.

The PV module rigid base sheet 19 can be a reinforced thermo-set plastic, honeycomb composite or other suitable material able to withstand the sun radiation heat with acceptable criteria of very small shape distortion and low linear coefficient of thermal expansion.

As can be apparent from described above inventive PV module, the PV cells layer 15 can be created by any kind of PV cells including very high efficiency cells developed lately by the industry. The PV cells can be connected to each other and to bus strip conductors by soldered tab conductors which are being well known to those skilled in the Art are not shown in this invention.

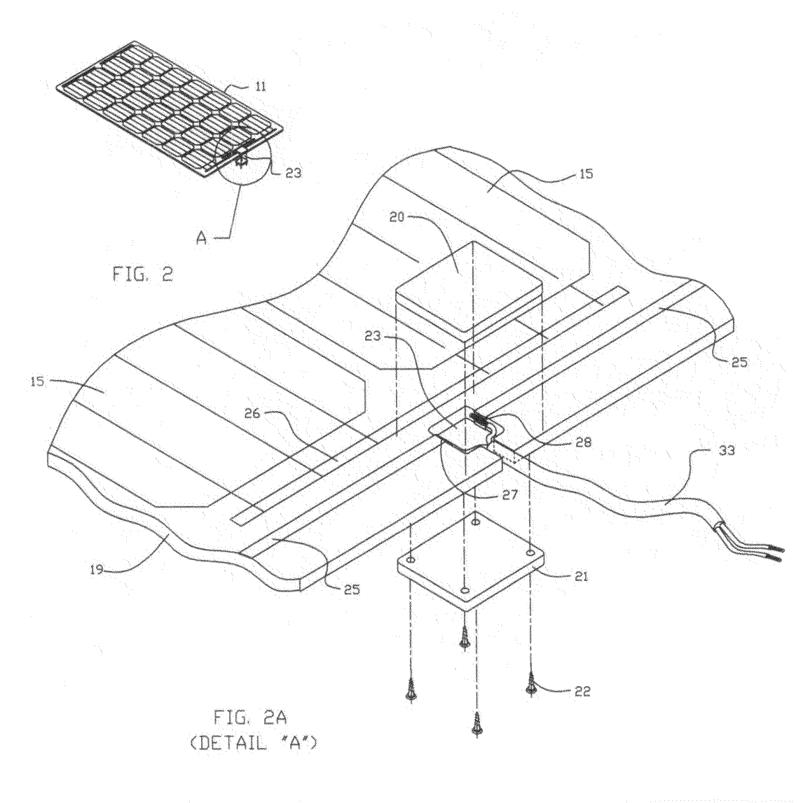

FIG. 2 presents an isometric view of the assembled inventive PV module 11 indicating area of detail ‘A” in the region of the termination chamber.

FIG. 2A shows the Detail “A” as an isometric enlarged local view of the PV module area with PV module output termination chamber 23 which is built in the PV module rigid base sheet 19. The drawing shows intermediate bus strip 26 connecting PV cells 15 and terminating bus strips 25 (+ and −) descending into the output termination chamber 23. The ends 27 and 28 of a PV module output cord 33 are soldered to the descended ends of the bus strips 25 in the termination chamber 23.

An upper cover dielectric plate 20, shown elevated above the termination chamber 23, shall be permanently adhered to the PV module rigid base sheet 19.

The chamber can be sealed by a silicone sealant to protect soldered connections. A lower cover dielectric plate 21 of the termination chamber 23 is removable and secured in place by screws 22. As can be seen in this drawing, the termination chamber assembly is very low profile allowing compact stacking of the inventive PV modules.

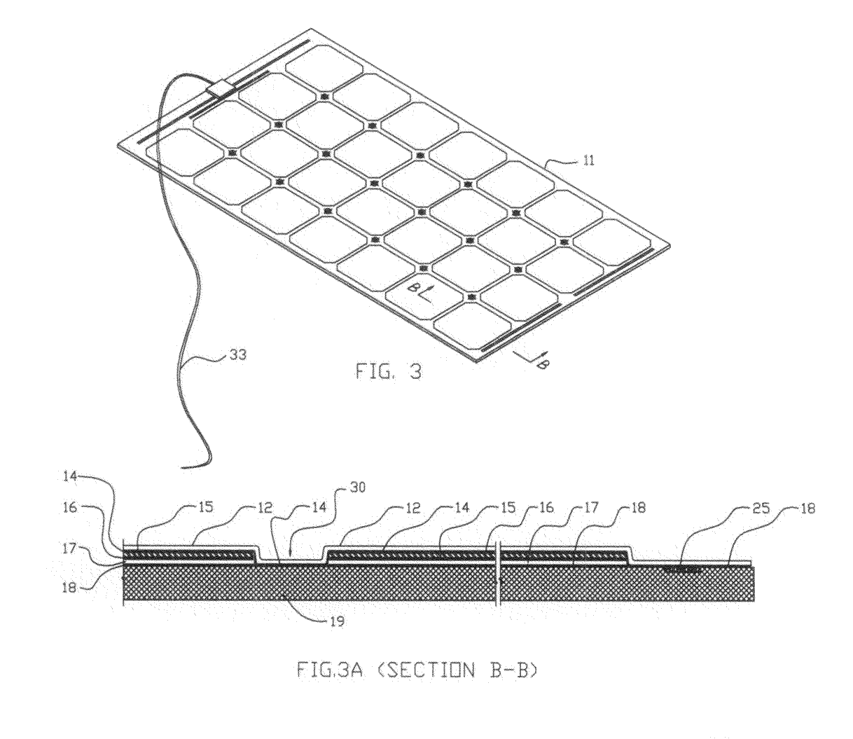

FIG. 3 depicts an isometric view of the fully assembled inventive PV module 11 with the output cord 33 and shows the area of Section “B-B”.

FIG. 3A presents the Section “B-B” view exposing cut view of the layers 12, 14, 15, 16, 17, 18 and the rigid base sheet 19.

As can be seen the space between PV cells 15 looks like groove accommodating an in-fold 30 of the front plastic film glazing layer 12 adhered to said PV module rigid base sheet 19 by the adhesive 14. Such in-folds, being a typical situation in the spaces between adjacent PV cells 15, provide a compensation for a linear thermal expansion and contraction of the front plastic film glazing layer 12 due to the difference of thermal linear expansion coefficients between the front plastic film glazing layer 12 and PV module rigid base sheet 19.

For instance, the thermal linear coefficients of expansion of some materials for the front plastic film glazing layer: FEP—75×10⁻⁶ in/in/° F., PTFE—73×10⁻⁶ in/in/° F., PET—33×10⁻⁶ in/in/° F.

the thermal linear coefficients of expansion of some materials for the PV module rigid base sheet: FRP—10 to 15×10⁻⁶ in/in/° F., Phenolic Composite—6 to 10×10⁻⁶ in/in/° F.

As can be seen, the difference is significant which can result in significant mechanical stresses causing bulging and pill off of the layers or/and bending module. The mechanical stress increases with increase of thickness of the front plastic film glazing layer 12.

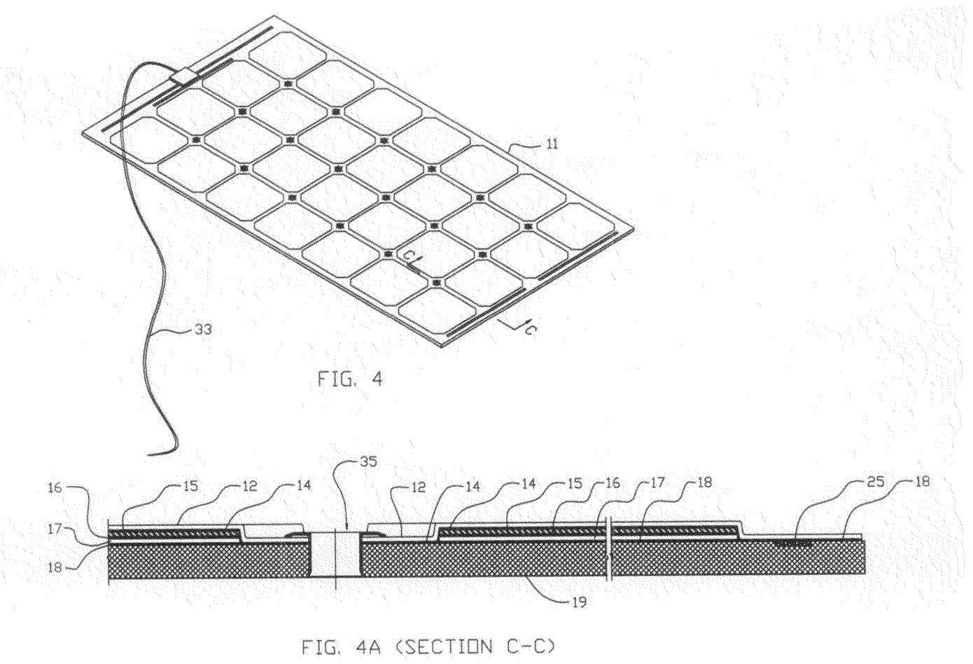

FIG. 4 presents an isometric view of the fully assembled inventive PV module 11 with the output cord 33 and shows the area of Section “C-C”.

FIG. 4A presents the Section “C-C” view exposing cut view of the layers 12, 14, 15, 16, 17, 18 and the PV module rigid base sheet 19.

As can be seen, the interspace between adjacent PV cells chamfered corners looks like recess with the plastic film glazing 12 adhered to the PV module rigid base sheet 19 by adhesive 14 and this bond is enhanced by an eyelet 35 installed in a hole drilled through the front plastic film glazing layer 12 and the PV module rigid base sheet 19. The holes reinforced by the eyelets 35 can be used for variety of mounting situations of the inventive PV module simplifying installation.

Bus conductor strip 25 is shown embedded in a groove of the base sheet 19 securing it in place.

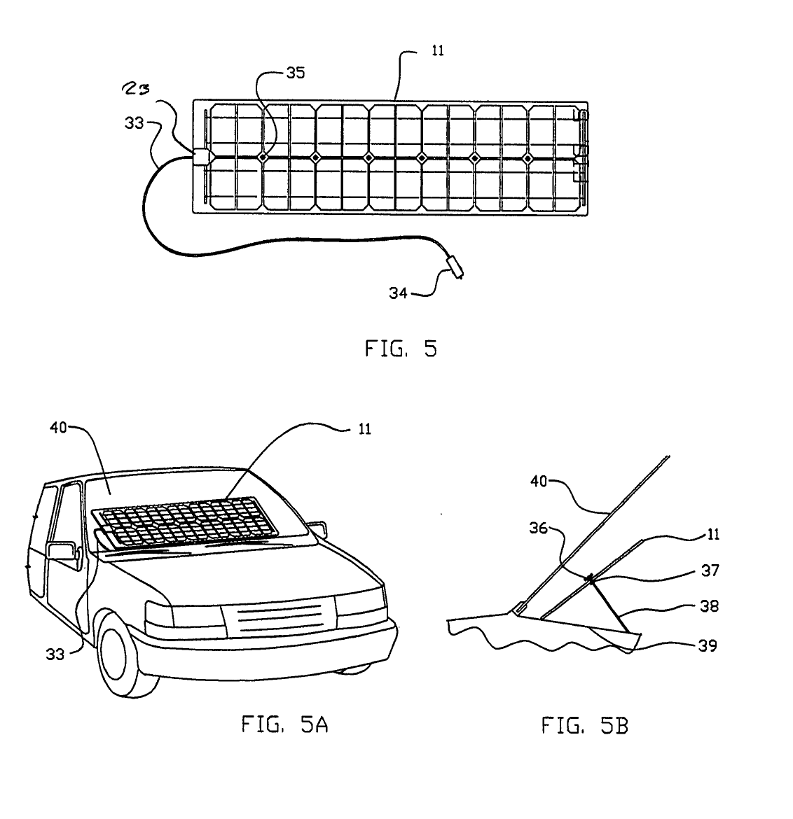

FIG. 5 shows one of several possible configurations and applications of the inventive PV module 11. I this case, presented portable PV module for automotive application as a portable PV module to work as a dash board sun radiation shield providing electric power for charging car battery. The module has mounting holes with eyelets 35 and cigarette lighter plug 34 connected to the module output cord 33. The module is equipped with a blocking diode to prevent back flow of current at low output. The diode can be installed in the output termination chamber 23 the cigarette lighter plug 34. The details of installation and connection of said blocking diode, being of the usual conventional design, old in the art, and well known in the structure and methods of operation to those skilled in the art, are omitted.

FIG. 5A shows installation of the inventive PV module 11 designed as a dashboard sun radiation protective shield being placed on a top of a dashboard behind a wind shield glass 40 of a car. The output cord 33 is plugged into a cigarette lighter socket.

FIG. 5B presents a side view of the inventive PV module 11 placed on the top of a car dashboard 39 and supported at an angular orientation by a removable support assembly attached to the module mounting hole and comprising at least one support rod 38, a nut 37 and a wing nut 36.

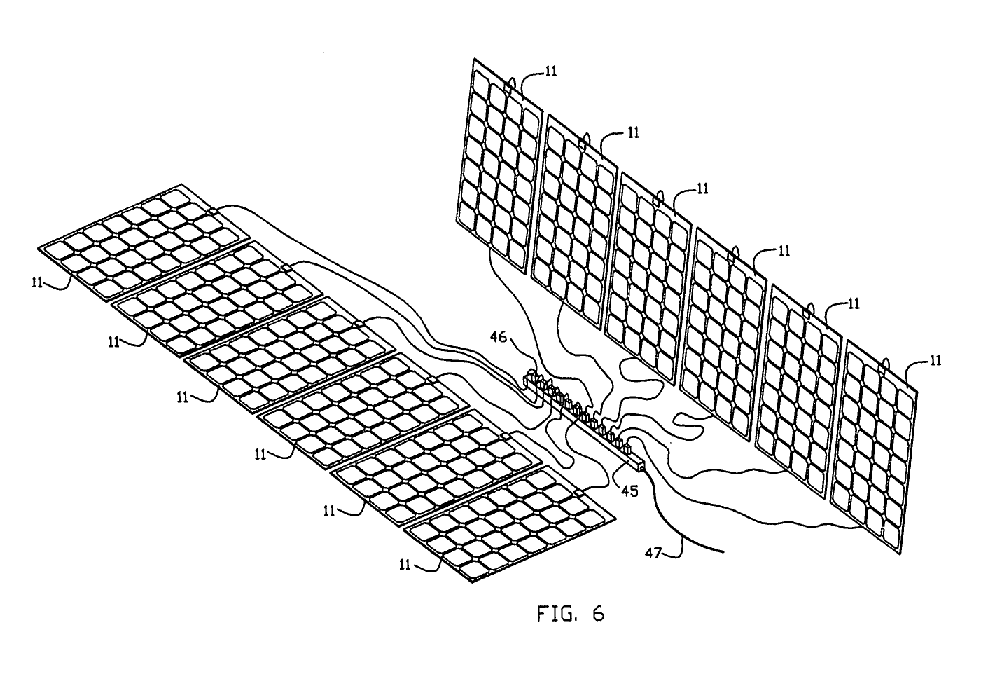

FIG. 6 shows an isometric view of possible arrangement and connection of the inventive PV modules 11 used in a portable setup. The modules output cords are equipped with proprietary DC plugs 46 being connected to a multi-outlet strip 45 connecting internally outputs of the PV modules in series and parallel manner to obtain proper combined DC output voltage and current of the system. In a portable application, output DC voltage of the system shall not exceed 60VDC level (IEC1010, UL3110, EN61010). The multi-outlet strip cable 47 can be connected to other devices of the system, not shown here, such as inverters, battery charge regulators and different types of loads. Their details of installation and connections, being of the usual conventional design, old in the art, and well known in the structure and methods of operation to those skilled in the art, are omitted.

Blocking and bypass diodes and short circuit devices can be installed into the multi-outlet strip 45 to provide all necessary protection. The details of installation and connection of said diodes and short circuit protection devices, being of the usual conventional design, old in the art, and well known in the structure and methods of operation to those skilled in the art, are omitted.

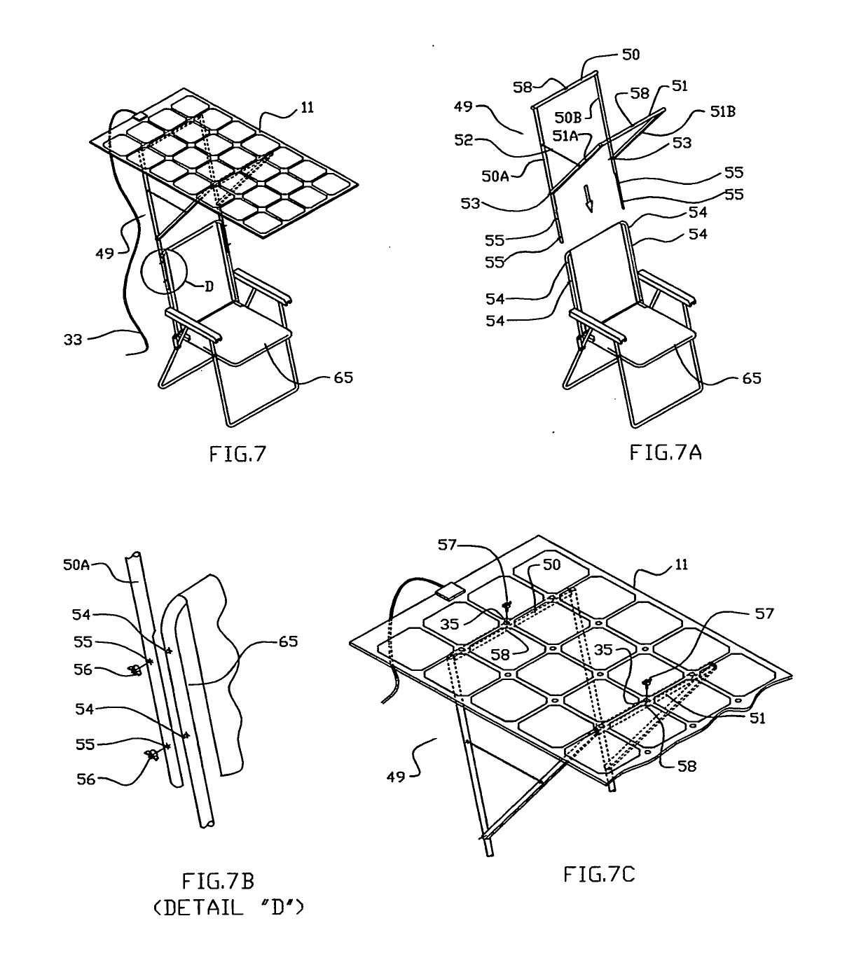

FIG. 7 shows the inventive PV module 11 with a power output cord 33 is mounted on a detachable and foldable structure 49 attached to a foldable armchair 65. The drawing, also, indicate the area of Detail “D” to be presented on the following drawing FIG. 7B.

FIG. 7A presents isometric view of a detachable and foldable mounting structure 49 for mounting the inventive PV module. The mounting structure 49 is shown detached from a foldable armchair 65. Said structure 49 comprises two C-frames, one of them is a rear C-frame with pair of lightweight members 50A, 50B upstanding from the back support of said arm chair 65 and detachably connected to it. The top ends of said members 50A and 50B are connected by a horizontal supporting transverse member 50. Another C-frame identified as a forward C-frame comprised a pair of lightweight members 51A and 51B are upstanding from said above members 50A and 50B and pivotally connected to them respectively by the pivoted connections 53 having transverse horizontal axis with details of installation being of the usual conventional design, old in the art, and well known in the structure and methods of operation to those skilled in the art, so they are omitted.

The top ends of said members 51A and 51B are connected by a horizontal supporting transverse member 51. Both said above members 50 and 51 have threaded holes 58 for mounting the inventive PV module. The lower ends of said members 50A and 50B are equipped with mounting holes 55 and the back support of the arm chair 65 has installed mounting screws 54 located to match the holes 55.

FIG. 7B presents an isometric view of Detail “D” showing attachment of the member 50A having round tubular shape and the end having longitudinally cut tube segment shape equipped with two holes 55, the back support of the arm chair 65 has installed mounting screws 54 located to match the holes 55, two wing nuts 56 are to secure said member 50A to be mounted on the screws 54, so said member 50A will be securely attached to the foldable armchair 65. This detail is typical for another side, member 50B.

It should be understood that described above elements are the preferred embodiments of releasable locking means for securing the foldable mounting structure 49 to a foldable armchair 65 without tools, another configurations of releasable locking means can be utilized which are not presented in his invention but are well known in the structure and methods of operation to those skilled in the art.

FIG. 7C is an isometric view of PV module 11 being mounted on the mounting structure 49 and being attached to this structure by wing screws 57 going through eyelets 35 of the mounting holes of the module 11 and threaded holes 58 located on horizontal supporting transverse members 50 and 51 of the mounting structure 49. PV module 11 serves as one important rigid element providing stability for the structure.

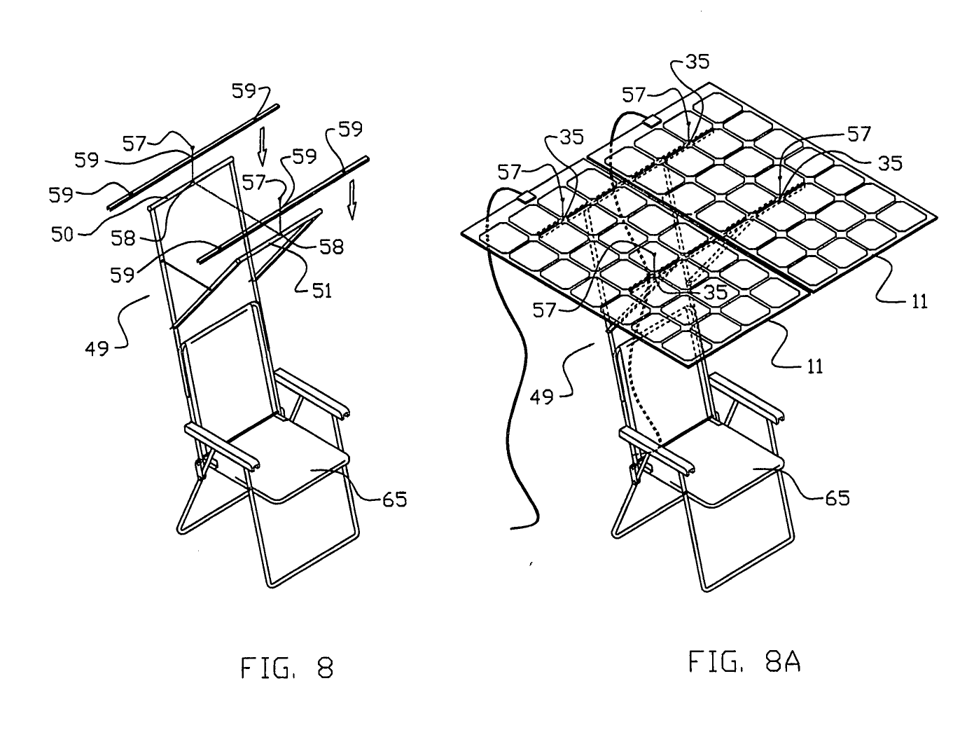

FIG. 8 is an isometric view of the detachable and foldable structure 49 for supporting two inventive PV modules. As can be seen on this drawing, the same structure 49 as was presented previously on the FIGS. 7-7C, added two new horizontal supporting channels 60 each having mounting holes 58 located at the middle of the channels length allowing said channels to be mounted on the horizontal supporting transverse members 50 an 51 each equipped with threaded hole 58 used for allowing wing screws 57 to secure the channels 60 to the members 50 and 51. Each said channel 60 is equipped with threaded holes 59.

FIG. 8A is an isometric view of two inventive PV modules 11 supported by the detachable and foldable structure 49. The PV modules are secured in place by wing screws 57 going through eyelets 35 of the mounting holes of the modules 11 and threaded holes 59 located on horizontal supporting transverse channels 60 attached to the mounting structure 49.

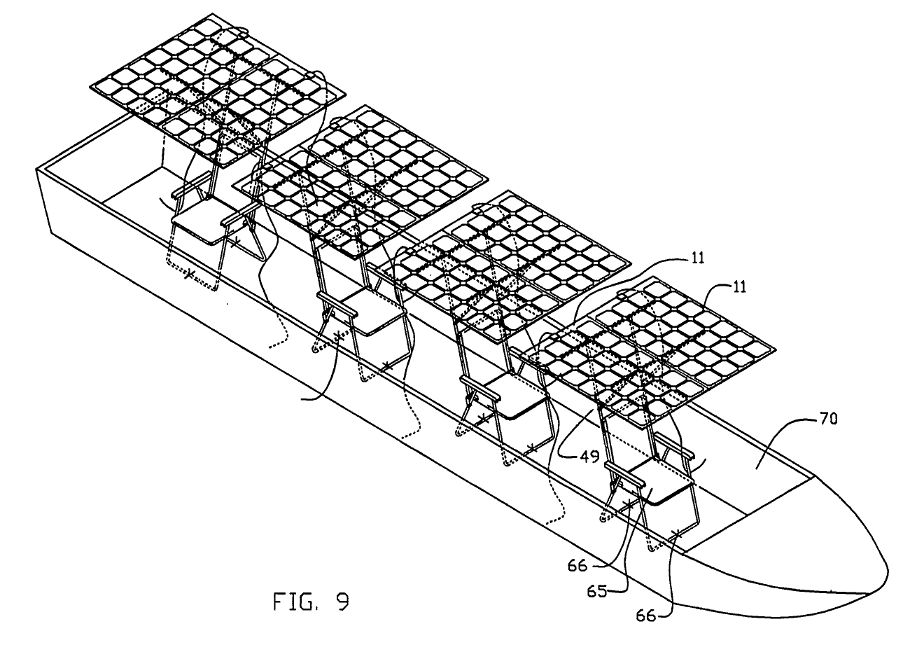

FIG. 9 is an isometric view of a conventional style boat 70 equipped by the portable inventive PV modules 11 mounted on detachable and foldable structures 49 attached to the armchairs 65 and serve as a part of a solar/electric power source for a propulsion system of the boat. The armchairs 65 are secured to the boat using releasable locking means 66, such as wing screws or other relevant methods which are of the usual conventional design, old in the art, and well known in the structure and methods of operation to those skilled in the art, so detailed presentation of them is omitted. All elements identified for one armchair assembly are typical for the all armchair assemblies shown on the boat. The PV modules can be connected to a one or several multi-outlet strips, as was presented on FIG. 6, connecting internally outputs of the PV modules in series and parallel manner to obtain proper combined DC output voltage and current of the system.

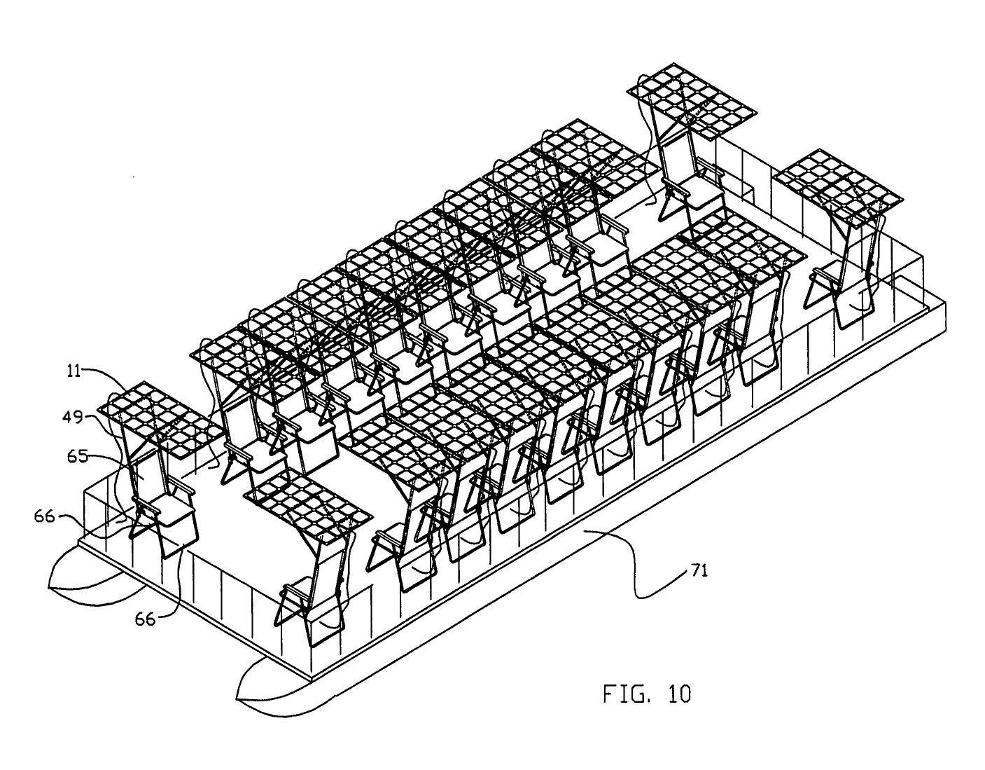

FIG. 10 is an isometric view of a pontoon style boat 71 equipped by the portable inventive PV modules 11 mounted on detachable and foldable structures 49 attached to the armchairs 65 and serve as a part of a solar/electric power source for a propulsion system of the boat. The armchairs 65 are secured to the boat using releasable locking means 66, such as wing screws or other relevant methods which are of the usual conventional design, old in the art, and well known in the structure and methods of operation to those skilled in the art, so detailed presentation of them is omitted. All elements identified for one armchair assembly are typical for the all armchair assemblies shown on the boat. The PV modules can be connected to a one or several multi-outlet strips, as was presented on FIG. 6, connecting internally outputs of the PV modules in series and parallel manner to obtain proper combined DC output voltage and current of the system.

I claim:

1. A frameless photovoltaic module constructed as a laminated sandwich comprising an optically transparent front plastic film glazing layer, an optically transparent upper adhesive layer, a PV cells layer which is a matrix of electrically connected PV cells, a middle adhesive layer adhering said PV cells to a PV cells back lining layer consisting of a matrix of an individual plastic film tiles having the same quantity, footprints and arrangement as the PV cells and another sides of said plastic film tiles are adhered to a PV module rigid base sheet by a lower adhesive layer, further, said front plastic film glazing layer, being adhered by said upper adhesive layer to said PV cells and to said PV module rigid base sheet, in spaces between said PV cells and the PV module rigid base sheet peripheral areas, forms in-folds in the grooved spaces between said PV cells which are formed combined thickness of said PV cells, said middle adhesive layer, said back lining plastic film tiles and said lower adhesive layer, where said in-folds allow compensation for thermal expansion and contraction of said front plastic film glazing layer, additionally, interspaces between adjacent PV cells chamfered corners are arranged with mounting holes drilled through the plastic film glazing layer and the PV module rigid base sheet and each said mounting hole is reinforced by an eyelet enhancing attachment of the PV module laminated sandwich system to the PV module rigid base sheet, additionally, said PV module rigid base sheet is equipped with bus conductor strips embedded in grooves of said base sheet and an output cord termination chamber of the PV module is constructed as a cutout in said base sheet and equipped with two dielectric cover plates, said cutout, being located close to the PV module rigid base sheet perimeter, is provided with a cut-through outlet neck for PV module output cord

2. The photovoltaic module of claim 1 equipped with detachable and foldable mounting structure for detachable installation on a foldable armchair where said structure comprises two C-frames, one of them is a rear C-frame with a pair of lightweight members upstanding from the back support of said arm chair and detachably connected to it, the top ends of said members are connected by a horizontal supporting transverse member and another C-frame identified as a forward C-frame comprising a pair of lightweight members upstanding from said above pair members of the rear C-frame and connected to them respectively by the pivoted connections each having transverse horizontal axis, and the top ends of said pair of members of the forward C-frame are connected by another horizontal supporting transverse member, so, both said above horizontal transverse members can support the inventive PV module release ably secured to them by releasable fastening means without tools, and, further, lower ends of said pair members of the rear C-frame are remove ably connected to a foldable armchair back support and are secured to it by another releasable fastening means without tools.
